(19) United States
(12) Patent Application Publication
(10) Pub. No.: US 2026/0362866 A1
(43) Pub. Date: Nov. 12, 2026

(54) LIGHT-EMITTING DEVICE ON SUBSTRATE

(71) Applicant: BOLB INC., LIVERMORE, CA (US)

(72) Inventors: JIANPING ZHANG, LIVERMORE, CA (US); YING GAO, LIVERMORE, CA (US); Ling Zhou, LIVERMORE, CA (US); Bin Zhang, LIVERMORE, CA (US)

(21) Appl. No.: 19/205,938

(22) Filed: May 12, 2025

(51) Int. Cl. H10H 20/856

(52) U.S. Cl. CPC H10H 20/856

(57) ABSTRACT

A light-emitting device with high light extraction efficiency, especially for deep ultraviolet emissions, is provided. Protrusion or depression features are formed on both surfaces of the substrate of the a light-emitting device to improve light extraction efficiency.

### FIELD OF THE INVENTION

The present invention relates in general to a semiconductor light emitting device and, more particularly, to an ultraviolet light-emitting diode formed on a substrate whose opposing surfaces are patterned with submicron-to-micron protrusions and/or depressions for improved optical power efficiency.

### DESCRIPTION OF THE RELATED ART

Ultraviolet (UV) light-emitting diodes (LEDs) with optical emission wavelengths in the range of 200-360 nm can be made of group-III nitride compound semiconductors such as ternary AlGaN alloys. A typical UV LED includes an n-AlGaN (or n-type AlGaN) structure, a p-AlGaN (or p-type AlGaN) structure, and a light-emitting structure commonly made of AlGaN multiple-quantum-well (MQW) sandwiched in-between the n- and p-AlGaN structures. An AlGaN structure can be made of an AlGaN layer or many AlGaN layers joint forces to deliver a better function, such as to improve material quality, conductivity and/or carrier confinement. The Al-contents in the AlGaN layers/structures determines the optical emission wavelengths of the LEDs. Emissions of wavelength less than 315 nm possess strong germicidal effect, making them ideal for food, water, air and surface disinfections.

Light generated in the AlGaN structures has small escape cones into free space, owing to total internal reflections as AlGaN materials are optical dense. This has limited the light extraction efficiency for deep UV LEDs to be as small as 16% even for a transparent 268 nm UV LED (Jianping Zhang et al 2022 Semicond. Sci. Technol. 37 07LT01).

In the past, U.S. Pat. No. 6,091,085 disclosed using semiconductor-substrate interface protrusions and/or depressions to scatter light out of LEDs, and in the following years, using patterned sapphire substrates (PSS) with periodic protrusions and depressions on the epitaxial surface has been a common practice to improve the light extraction efficiency of group-III nitride based visible LEDs. Examples can be found in the US patents U.S. Pat. Nos. 9,012,936, 9,337,390, 9,385,275, 9,812,322, 9,947,830, 10,217,894, 10,312,409, et al. The contents of the above-mentioned US patents are herewith incorporated by reference in its entirety.

There are also efforts to make use of patterned sapphire substrates for UV LEDs, as seen in the US patents U.S. Pat. Nos. 9,412,586, 9,660,140, 10,697,089 and 12,132,147. The contents of the above-mentioned US patents are herewith incorporated by reference in its entirety.

However, though the PSS technology works excellently well for visible LEDs, gaining light-extraction efficiency (T) more than 80% up to 90%, it has not performed satisfactorily for deep UV LEDs. A deep UV LED considered in the present disclosure emits light of wavelength in the range of 200-360 nm, which is readily absorbed by GaN and small Al-content AlGaN materials. For this reason, most deep UV LEDs have light self-absorption issues from their p-type AlGaN structures. Furthermore, the p-side reflectance of deep UV LEDs is fundamentally limited by the lack of highly reflective p-type ohmic contact, leading to additional light loss.

### SUMMARY OF THE INVENTION

The present invention discloses LEDs on a substrate with high light extraction efficiency, especially for deep ultraviolet emissions, promising to a wall-plug-efficiency roadmap up to 45% for deep UV LEDs. The present invention is directed to a light-emitting device which includes:
a light-emitting structure, comprising an n-type semiconductor structure, a light-emitting active region, and a p-type semiconductor structure;
a reflector formed on the p-type semiconductor structure;
a substrate, providing an epitaxy surface supporting the light-emitting structure and a backside surface extracting light out of the light-emitting device;
wherein the epitaxy surface is patterned with protrusion or depression features, the protrusion or depression features on the epitaxy surface have a small base dimension d₁ in the range of 0-400 nm, a large base dimension D₁ in the range of 500-1000 nm, and a feature depth or height H₁ in the range of 350-750 nm, and the epitaxy surface has a flat surface ratio in the range of 9-60%;
wherein the backside surface is patterned with protrusion or depression features, the protrusion or depression features on the backside surface have a small base dimension d₂ in the range of 0-400 nm, a large base dimension D₂ in the range of 800-3000 nm, and a feature depth or height H₂ in the range of 550-2100 nm, and the backside surface has a flat surface ratio in the range of 0-60%.

### BRIEF DESCRIPTION OF THE DRAWINGS

The accompanying drawings, which are included to provide a further understanding of the invention and constitute a part of this application, illustrate embodiments of the invention and together with the description serve to explain the principle of the invention. Like reference numbers in the figures refer to like elements throughout, and a layer can refer to a group of layers associated with the same function.

FIG. 1 illustrates a light-emitting device structure, made of multiple layers of different refractive indices, for light extraction efficiency calculation.

FIG. 2 illustrates a light-emitting structure L₁ formed on a substrate S₁, with light being extracted from L₁ through S₁ into an extraction medium M₁, of respective refractive indices of n₁, n₂, and n₃, where n₁>n₂>n₃.

FIG. 3 illustrates a light escape cone for light emitted in an optically dense medium entering into an optically less dense medium.

FIG. 4 shows a cross-sectional illustration of a light-emitting structure L₁ formed on a double-surface patterned substrate S₁ according to one aspect of the present invention, where the opposing surfaces of substrate S₁ being patterned to form protrusions and depressions into the light-emitting structure L₁ and medium M₁, respectively.

FIG. 5 illustrates a plan view of a portion of a substrate surface with protrusion/depression pattern features. The insert shows a cone protrusion and a cone depression.

FIG. 6 shows a cross-sectional illustration of a substrate S₁, where the epitaxy surface to receive epitaxial growth is patterned of depressions and the backside surface is patterned of protrusions, respectively.

FIG. 7(a) shows a scanning electron microscopic plan view of a portion of a patterned substrate surface comprising of hexagonal packing circular cone depressions.

FIG. 7(b) shows a scanning electron microscopic cross-sectional view of a circular cone depression seen in FIG. 7(a).

FIG. 7(c) shows a scanning electron microscopic plan view of a portion of a patterned substrate surface comprising of hexagonal packing circular cone protrusions.

FIG. 7(d) shows a scanning electron microscopic bird's-eye view of circular cone protrusions seen in FIG. 7(c).

FIG. 8 shows a layered structure of an LED formed on a double-surface patterned substrate according to one aspect of the present disclosure.

FIG. 9 shows a layered structure of an LED formed on a double-surface patterned substrate according to another aspect of the present disclosure.

FIG. 10 shows a roadmap of wall-plug efficiency for deep UV LEDs, and the wall-plug efficiency dependence on the p-side reflectance and the reflectance at the semiconductor/substrate and substrate/extraction medium interfaces.

### DETAILED DESCRIPTION OF EMBODIMENTS

Throughout the specification, the term group III nitride in general refers to metal nitride with cations selecting from group IIIA of the periodic table of the elements. That is to say, III-nitride includes AlN, GaN, InN and their ternary (AlGaN, InGaN, InAlN) and quaternary (AlInGaN) alloys. In this specification, a quaternary can be reduced to a ternary for simplicity if one of the group III elements is significantly small so that its existence does not affect the intended function of a layer made of such material. For example, if the In-composition in a quaternary AlInGaN is significantly small, smaller than 1%, then this AlInGaN quaternary can be shown as ternary AlGaN for simplicity. Using the same logic, a ternary can be reduced to a binary for simplicity if one of the group III elements is significantly small. For example, if the In-composition in a ternary InGaN is significantly small, smaller than 1%, then this InGaN ternary can be shown as binary GaN for simplicity. Group III nitride may also include small amount of transition metal nitride such as TiN, ZrN, HfN with molar fraction not larger than 10%. For example, III-nitride or nitride may include AlₓIn_{y}Ga_{z}Ti_{(1-x-y-z)}N, AlₓIn_{y}Ga_{z}Zr_{(1-x-y-z)}N, AlₓIn_{y}Ga_{z}Hf_{(1-x-y-z)}N, with (1−x−y−z)≤10%.

As well known, light-emitting devices including light-emitting diodes (LEDs) and laser diodes adopt a light-emitting structure, which comprises a light-emitting active region (AR), commonly made of multiple-quantum well (MQW)), an n-type and a p-type semiconductor structure, which inject electrons and holes into the active region, respectively. In general, the MQW AR is of a slightly larger refractive index than those of the n-type and p-type semiconductor structures, but the difference is trivial for most LEDs. On the other hand, the light-emitting structure is generally formed on a transparent substrate, whose refractive index can be significantly lower than that of the light-emitting structure. There is a total internal reflection (TIR) loss for light propagating from an optically denser medium into a less dense medium. Furthermore, the surrounding ambient, or medium, around the LED, is usually free space, of refractive index being only 1, leading to further TIR loss.

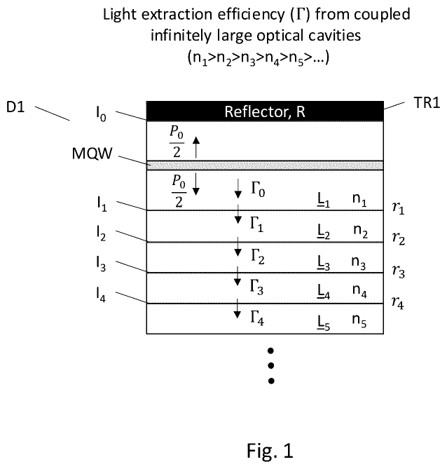

In this sense, optimizing optical interfaces in an LED is of critical importance for high light extraction efficiency (LEE, T). The light-extraction efficiency of an LED can be calculated provided that some assumptions are met, according to the present disclosure. FIG. 1 illustrates a bottom emitting LED structure D₁, made of multiple semiconductor or dielectric layers Lᵢ (i=1, 2, 3, 4, 5, . . . ) stacked in sequence of different refractive indices nᵢ (i=1, 2, 3, 4, 5, . . . ), respectively. And L₁ is a light-emitting structure, capped with a reflector TR1 of reflectance R.

To calculate the light extraction efficiency Γ through the bottom surface of the LED structure, we assume:
1) There is no light loss in the LED structure except at the reflector TR1;
2) There is no reflection when light propagating from an optically less dense medium into an optically denser medium;
3) nᵢ>nⱼ for j>i;
4) The optical cavities are infinitely large, i.e., there is no light escape at the sidewalls of the LED structure.

With these assumptions, referring to FIG. 1, there are multiple optical interfaces Iᵢ (i=1, 2, 3, 4, . . . ) of respective reflectance rᵢ (i=1, 2, 3, 4, . . . ) in the LED structure formed between layers L₁ and Lᵢ₊₁. Also included is an optical interface I₀ of reflectance R, formed between reflector TR1 and the light-emitting structure L₁. For light propagating from an optically denser medium Lᵢ (i≥1) into a less dense medium Lᵢ₊₁, there is a reflectance rᵢ determined by TIR.

When light of optical power P₀ is generated by the MQW AR, half of the power would go up and get reflected back by reflector TR1, so there is

$$\frac{1 + R}{2}$$

P₀ available to be extracted out of L₁ into L₂. Let

$${Γ}_{0} = \frac{1 + R}{2} ,$$

and let Γᵢ (i≥1) be the light extraction efficiency from layer Lᵢ to layer Lᵢ₊₁, we have the following equations:

$${Γ}_{0} = \frac{1 + R}{2} , {Γ}_{1} = \frac{1 - {r}_{1}}{1 - {Rr}_{1}} , {Γ}_{2} = \frac{1 - {r}_{2}}{1 - {Rr}_{2} {Γ}_{1}} , {Γ}_{3} = \frac{1 - {r}_{3}}{1 - {Rr}_{3} {Γ}_{1} {Γ}_{2}} , {Γ}_{4} = \frac{1 - {r}_{4}}{1 - {Rr}_{4} {Γ}_{1} {Γ}_{2} {Γ}_{3}} , … , \qquad eq . ( 1 )$$

and the final light extraction efficiency (Γ) of the LED is given by,

Γ=Πᵢ₌₀Γᵢ eq. (2)

Eqs. (1) and (2) thus give an analytic model of light-extraction efficiencies for LEDs. It can be shown that

$$\frac{\partial Γ}{\partial R} > 0 and \frac{\partial Γ}{\partial {r}_{i}} < 0 .$$

This means that to increase LEE one needs to increase the reflectance R of reflector TR1, meanwhile reduce the number of the optical interfaces and the interface reflectance rᵢ.

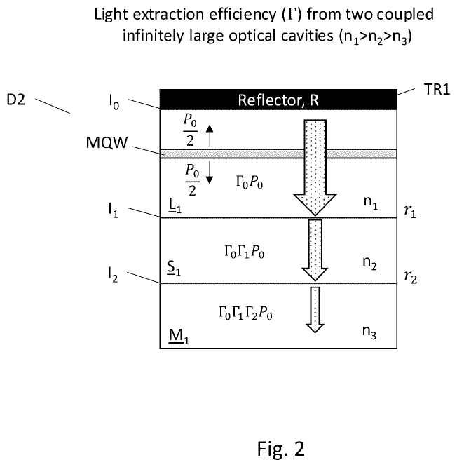

For a bottom emitting AlGaN based deep UV LED structure D₂ with a light-emitting structure L₁ formed on a sapphire substrate S₁, as illustrated in FIG. 2, there are essentially three optical interfaces: interface I₀ between reflector TR1 and the light-emitting structure L₁, interface I₁ between L₁ and S₁, interface I₂ between S₁ and extraction medium M₁. Medium M₁, used to extract light out of the light-emitting structure, can be free space, or a lens made of sapphire, quartz, or fluoropolymers. The lens can be hemispheric and of size much larger (>2×) than the LED chip to which it attaches, ideally able to extract 100% light out from the lens to free space. According to eqs. (1) and (2), the light extraction efficiency of LED structure D₂ can be given by an analytic model governed by eq. (3).

$$Γ = \frac{1 + R}{2} \frac{( 1 - {r}_{1} ) ( 1 - {r}_{2} )}{( 1 - {Rr}_{1} ) - {Rr}_{2} ( 1 - {r}_{1} )} \qquad eq . ( 3 )$$

As seen, here Γ is determined by the parameters R, r₁, and r₂. To maximize Γ, one needs to maximize R and minimize r₁ and r₂, respectively.

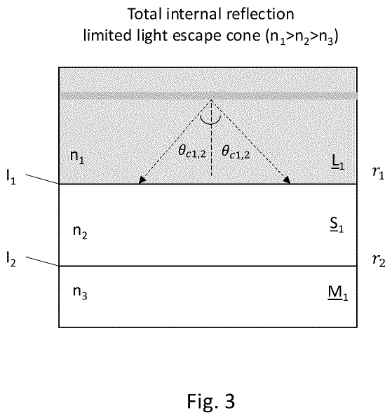

For optically smooth interfaces I₁ and I₂ as shown in FIG. 3, r₁, and r₂ can be figured out by considering the light escape cones determined by TIR. For example, when light is transmitted from the optically denser L₁ into the optically less dense S₁ of refractive indices of n₁ and n₂, respectively, the critical angle of TIR is

$${θ}_{c 1 , 2} = arcsin ( \frac{{n}_{2}}{{n}_{1}} ) ,$$

which defines a light escape cone of solid angle 2π (1−cos θ_{c1,2}). Assuming the emissions from the MQW AR are of radiant intensity independent of the emission angle, we have r₁=cos θ_{c1,2}. Similarly, we have r₂=cos θ_{c2,3}, where

$${θ}_{c 2 , 3} = arcsin ( \frac{{n}_{3}}{{n}_{2}} ) .$$

For a 265 nm deep UV LED formed on a flat sapphire substrate with a fluoropolymer hemisphere lens, we have n₁, n₂ and n₃ to be 2.35, 1.83, and 1.32, respectively. These translate into r₁ and r₂ being 62.4% and 69.4%, respectively. For the cases of R=0% and 30%, then this 265 nm deep UVLED has a light extraction efficiency of 5.75% and 10.18%, respectively, far from satisfactory.

The embodiments shown below of the present disclosure aim to decrease r₁ and r₂, and increase R for the general deep UV LED structure D₂ illustrated in FIG. 2.

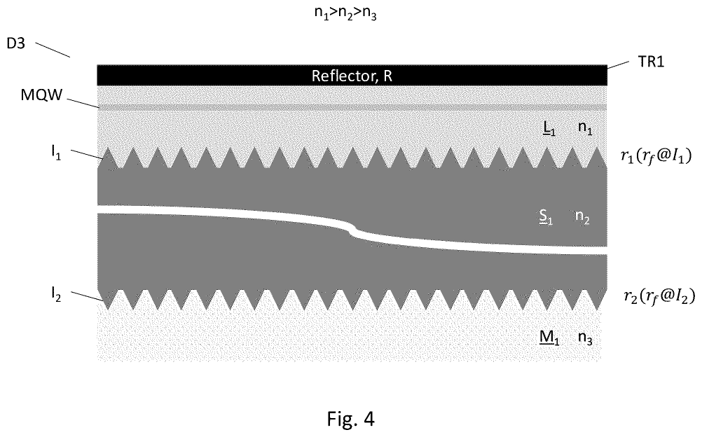

Illustrated in FIG. 4 is an embodiment of a deep UV LED structure D₃, possessing intentionally patterned/roughened interfaces I₁ and 12, between the light-emitting structure L₁ and substrate S₁, and between substrate S₁ and extraction medium M₁, respectively. The roughened interfaces I₁ and I₂ are designed to interrupt the TIR so that to achieve a much lower reflectance r₁ and r₂, respectively. The roughened interfaces can be achieved via epitaxial growth of the light-emitting structure L₁ on a double-surface patterned substrate (DSPS), which has a roughened surface to receive epitaxial growth of L₁ and a roughened surface to extract light into the extraction medium M₁.

In an embodiment, roughened surfaces of a DSPS can be realized using standard semiconductor processing technology, including pattern transfer using optical/electron/nanoimprint lithography and pattern formation using reactive ion etch or inductively coupled plasma etch. The substrate material is preferred to be transparent to the light emitted by the light-emitting structure L₁. For example, if the emissions are in the deep ultraviolet regime, i.e., 200-360 nm, substrate S₁ is preferred to be selected from sapphire, AlN diamond, and quartz.

The pattern features on the surfaces, being protrusions or depressions, are optionally to be tightly packed, to give a maximal surface roughness.

For group III nitride devices, the pattern features are optionally to be hexagonal packing cone protrusions or depressions. A cone protrusion on substrate S₁ is optionally made of the same material as the substrate, and a cone depression into substrate S₁ is a cone shaped void in the substrate. A cone protrusion/depression, or a protrusion/depression cone, used interchangeably in the present disclosure, means the same thing. And a cone can be truncated, is optionally a circular cone.

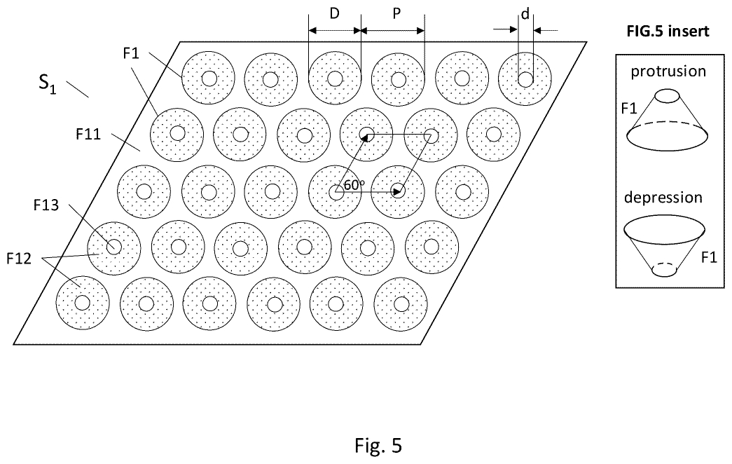

FIG. 5 illustrates a plan view of a portion of a substrate (S₁) surface patterned according to an embodiment of the present disclosure. As shown, the pattern features F1, being protrusions or depressions, are hexagonal packing circular cones (optionally truncated). The insert to FIG. 5 illustrates a protrusion cone and a depression cone. A unit cell to configure the pattern is shown to be an equilateral parallelogram, or a rhombus of two interior angles equal to 60°. Also shown, the period (or pitch) of the pattern features F1 is P, and the large and small bases of the cones are of diameters D and d, respectively. Pattern features F1 separate the surface area into two types: slanted (or inclined) surfaces F12 and flat surfaces F11 and F13. The flat surfaces remain parallel to the original substrate surface prior to the surface patterning, and the slanted surfaces are inclined to the flat surfaces, optionally with an inclination angle in the range of 30°-75°, or 40°-65°. Flat surface F11 accounts for the surface area surrounding the features F1, and flat surfaces F13 are composed of the surface areas of the small base planes of the truncated cones.

Flat surfaces F11 and F13 therefore can provide epitaxial growth bases and slanted surfaces F12 are to be buried by epitaxial layers when epitaxial layers on flat surfaces F11 and F13 coalesce. When a light-emitting structure L₁ is epitaxially formed on substrate S₁, such as one like the embodiment shown in FIG. 4, flat surfaces F11 plus F13 and slanted surfaces F12 therefore are converted into flat and slanted interface areas of interface I₁, respectively. The flat interface area can reflect light backward to the light-emitting structure L₁ due to TIR, contributing to light extraction loss, however, the slanted interface area will reflect and refract light forward into substrate S₁, leading to improved light extraction efficiency. The similar light extraction enhancement effect is true for interface I₂ shown in FIG. 4, which is patterned according to the present disclosure. To maximize the light extraction efficiency, it is therefore desirable to have the least flat interface areas on the interfaces I₁ and 12. An importance concept, flat surface ratio, r_{f}, of a patterned surface, is therefore introduced and to be defined in the following. It is pointed out firstly that a minimal flat surface ratio is needed to facilitate a good epitaxial growth on interface I₁. The minimal flat surface ratio depends on multiple factors such as the dimensions of the pattern features and the material composition of the light-emitting structure L₁.

In this disclosure, we define a flat surface ratio, r_{f}, for a patterned surface as the ratio of the flat surface area of a patterned surface to the area of the original surface prior to the surface patterning. According to this definition, the flat surface ratio of a smooth un-patterned surface is 100%. Therefore, according to one aspect of the present disclosure, flat surface ratio, r_{f}, can be used as a figure of merit for the surface/interface reflectance rᵢ, for example, one can assume that the interface reflectance rᵢ is proportional to r_{f}, or assume rᵢ=r_{f} in order to minimize the interface reflectance according to one aspect of the present disclosure. The flat surface ratio r_{f} for a surface patterning shown in FIG. 5 is given by

$${r}_{f} = 1 - \frac{π ( {D}^{2} - {d}^{2} )}{2 \sqrt{3} {P}^{2}} .$$

As seen, r_{f} equals 9.31% when d=0 and P=D. And r_{f} can reach zero if allowing d=0 and D>P. When d=0, the small cone bases vanish, so do the flat surfaces F13; when D>P, the neighboring pattern features F1 start to overlap, forming merged large cone bases and resulting in an area reduction of the flat surface area F11; especially when

$$D \geq \frac{2}{\sqrt{3}} P ,$$

flat surface F11 vanishes. So, under the conditions of d=0 and

$$D \geq \frac{2}{\sqrt{3}} P ,$$

flat surface areas F13 and F11 vanish and slanted surfaces F12 remain, achieving a zero flat surface ratio.

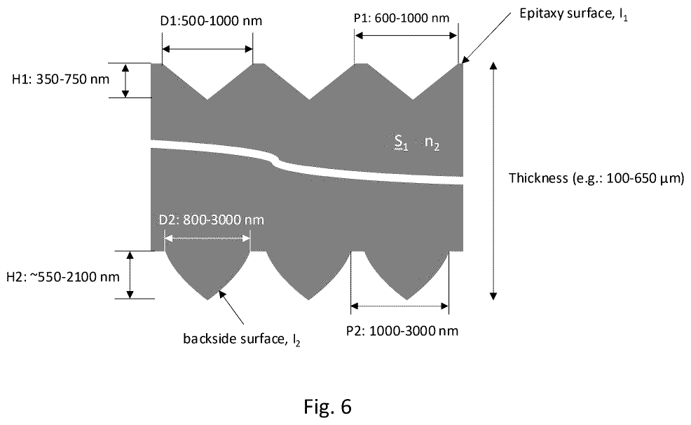

Shown in FIG. 6 is a cross-sectional illustration of a DSPS substrate S₁ having patterned epitaxy and backside surfaces according to an embodiment of the present disclosure. The substrate is optionally of a total thickness of a few hundred microns, such as 100-650 μm. The epitaxy surface (or top surface) is to receive epitaxial growth, therefore to define an interface I₁, and the backside surface is for light extraction into medium M₁, therefore to define an interface I₂. The epitaxy surface can be optionally patterned of micro depressions and the backside surface can be patterned of micro protrusions, respectively. The pattern features are optionally hexagonal packing micro cone depressions or protrusions, in a plan view as illustrated in FIG. 5. Or, the epitaxy surface can be optionally patterned of truncated micro cone protrusions and the backside surface can be patterned of micro protrusions or depressions, respectively.

Optionally, the pattern features on the epitaxy surface have a period P₁ in the range of 600-1000 or 700-900 nm, a small cone base diameter d₁ in the range of 0-400 or 100-200 nm, a large cone base diameter D₁ in the range of 500-1000 or 600-800 nm, and a feature depth or height H₁ in the range of 350-750 or 450-550 nm. Optionally, dimensions like the period, diameters of the large and small cone bases are selected to have a flat surface ratio r_{f} in the range of 9-60%, or 10-50%, or 15-40%, or 20-35%.

Optionally, the pattern features on the backside surface have a period P₂ in the range of 1000-3000 or 1500-2000 nm, a small cone base diameter d₂ in the range of 0-400 or 100-200 nm, a large cone base diameter D₂ in the range of 800-3000 or 1000-2000 nm, and a feature depth or height H₂ in the range of 550-2100 or 900-1500 nm. Optionally, dimensions like the period, diameters of the large and small cone bases are selected to have a flat surface ratio r_{f} in the range of 0-60%, or 10-50%, or 20-30%.

Optionally, the pattern features on the backside surface have a small cone base diameter d₂ equal to 0 nm, a period P₂ equal to, or less than, or larger than the large cone base diameter D₂, in order to achieve a flat surface ratio r_{f} in the range of 0-9.3%.

As the backside surface of substrate S₁ is only used for light extraction, not for epitaxial growth, it is preferred that there are only micro slanted surfaces F12 existing on the backside surface, with no flat surfaces F11 and F13 on the backside surface (r_{f}=0). The inclination angle of the slanted surfaces F12 is optionally in the range of 30°-75°, or 40°-65°. The pattern features can also be of any other type of periodically distributed micro pyramids besides circular cones. In this case, the pattern features on the epitaxy surface have a period P₁ in the range of 600-1000 nm, a small base dimension (defined as the longest length of the small base and being the diameter for a small cone base) d₁ in the range of 0-400 nm, a large base dimension (defined as the longest length of the large base and being the diameter for a large cone base) D₁ in the range of 500-1000 nm, and a feature depth or height H₁ in the range of 350-750 nm. Optionally, dimensions like the period, dimensions of the large and small pyramid bases are selected to have a flat surface ratio r_{f} in the range of 9-60%, or 10-50%, or 15-40%, or 20-35%. The pattern features on the backside surface have a period P₂ in the range of 1000-3000 nm, a small base dimension (defined as the longest length of the small base and being the diameter for a small cone base) d₂ in the range of 0-400 nm, a large base dimension (defined as the longest length of the large base and being the diameter for a large cone base) D₂ in the range of 800-3000 nm, and a feature depth or height H₂ in the range of 550-2100 nm. Optionally, dimensions like the period, dimensions of the large and small pyramid bases are selected to have a flat surface ratio r_{f} in the range of 0-60%, or 10-50%, or 20-30%.

Furthermore, in some embodiments, the pattern features can be randomly distributed on the backside surface without being in a periodic pattern.

In an embodiment, the pattern features on the epitaxy surface are hexagonal packing micro cone depressions with vanishing small cone bases, having a period P₁ in the range of 600-1000 nm, a large cone base diameter D₁ in the range of 500-900 nm, and a feature depth or height H₁ in the range of 350-750 nm. The period P₁ and the large cone base diameter D₁ satisfy 300 nm≥P₁−D₁≥100 nm. Wherein the pattern features on the backside surface are hexagonal packing micro cone protrusions, having a period P₂ in the range of 1000-3000 nm, a small cone base diameter d₂ in the range of 0-400 nm, a large cone base diameter D₂ in the range of 800-3000 nm, and a feature depth or height H₂ in the range of 550-2100 nm. By selecting proper combination of P₂, d₂, D₂ and H₂, the backside surface is patterned to possess a flat surface ratio r_{f} in the range of 0-30%, or 10-20%, or 5-15%.

In another embodiment, the pattern features on the epitaxy surface are hexagonal packing micro cone protrusions with a small cone base diameter d₁ in the range of 100-400 nm, and the cone protrusions have a period P₁ and a large cone base diameter D₁ satisfying D₁=P₁ so that flat surface area F11 on the epitaxy surface is small, wherein the pattern features on the backside surface are hexagonal packing micro cone protrusions so that the backside surface comprises micro slanted surfaces F12 of inclination angle in the range of 30°-75°, or 40°-65°, and the backside surface possesses a flat surface ratio r_{f} in the range of 0-30%, or 5-20%, or 10-15%.

In another embodiment, the pattern features on the epitaxy surface are hexagonal packing micro cone protrusions with a small cone base diameter d₁ in the range of 100-400 nm, and the cone protrusions have a period P₁ and a large cone base diameter D₁ satisfying

$${D}_{1} \geq \frac{2}{\sqrt{3}} {P}_{1}$$

so that flat surface F11 on the epitaxy surface vanishes, wherein the pattern features on the backside surface are hexagonal packing micro cone protrusions so that the backside surface comprises micro slanted surfaces F12 of inclination angle in the range of 30°-75°, or 40°-65°, and the backside surface possesses a flat surface ratio r_{f} in the range of 0-30%, or 5-20%, or 10-15%.

In still another embodiment, the pattern features on the epitaxy surface are hexagonal packing micro cone protrusions with a small cone base diameter d₁ in the range of 100-400 nm, and the cone protrusions have a period P₁ and a large cone base diameter D₁ satisfying

$${D}_{1} \geq \frac{2}{\sqrt{3}} {P}_{1}$$

so that flat surface F11 on the epitaxy surface vanishes, wherein the pattern features on the backside surface are hexagonal packing micro cone depressions so that the backside surface possesses a flat surface ratio r_{f} in the range of 0-30%, or 5-20%, or 10-15%.

In yet another embodiment, the pattern features on the epitaxy surface are hexagonal packing micro cone depressions with vanishing small cone bases, and the cone depressions have a period P₁ and a large cone base diameter D₁ satisfying 300 nm≥P₁−D₁≥100 nm, wherein the pattern features on the backside surface are hexagonal packing micro cone depressions so that the backside surface possesses a flat surface ratio r_{f} in the range of 0-30%, or 5-20%, or 10-15%.

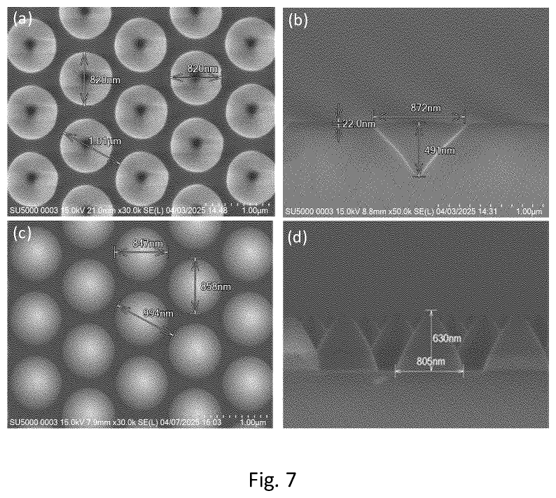

A double-surface patterned sapphire substrate has been fabricated using standard semiconductor processing technology, where the epitaxy surface is patterned with circular cone depressions and the backside surface is patterned with circular cone protrusions. FIG. 7(a) shows a scanning electron microscopic (SEM) plan view of a portion of the patterned epitaxy surface, as seen, the epitaxy surface comprises hexagonal packing circular cone depressions, with a period about 1000 nm, a large cone base diameter about 820-870 nm, and a small cone base diameter approaching 0 nm, resulting in a flat surface ratio r_{f} in the range of 31.4-39.0%. FIG. 7(b) shows a cross-sectional SEM micrograph of a circular cone depression shown in FIG. 7(a), observing the depth of the cone depression to be about 490 nm. FIG. 7(c) shows a SEM micrographic plan view of a portion of the patterned backside surface, comprising hexagonal packing circular cone protrusions, with a period about 1000 nm, a large cone base diameter about 800-860 nm, and a vanishing small cone base, resulting in a flat surface ratio r_{f} in the range of 32.9-42.0%. And a SEM bird's-eye view of the circular cone protrusions measures the cone height to be around 630 nm, as seen FIG. 7(d).

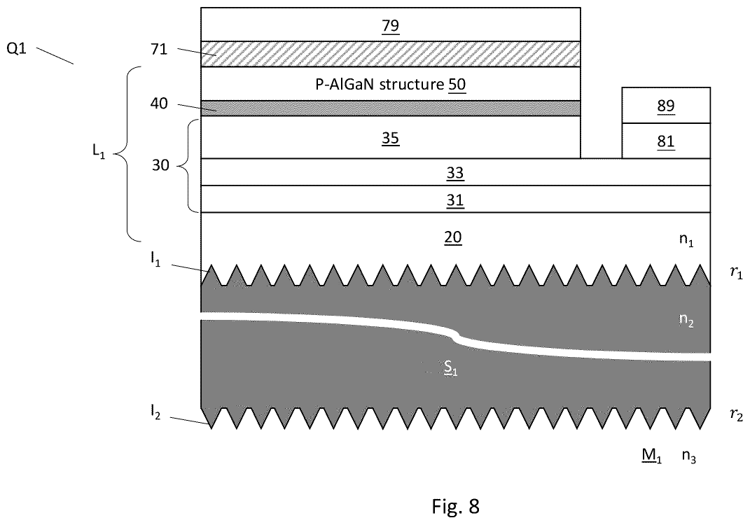

Illustrated in FIG. 8 is a cross-sectional schematic view of a UV LED Q1, comprising a light-emitting structure L₁ formed over a double-surface patterned substrate S₁ according to an embodiment of the present invention. Substrate S₁ can be selected from c-plane sapphire, AlN, SiC, quartz, diamond, and the like. The light-emitting structure L₁ comprises a template 20, an n-AlGaN structure 30, an MQW active-region 40, and a p-AlGaN structure 50. Formed over substrate S₁ is template 20, which can be a thick AlN layer or an AlGaN layer of high-Al-content, for example, with a thickness of 2.0-6.0 μm, to fully coalesce on the substrate S₁ to form an interface I₁. Formed over template 20 is a thick n-AlGaN structure 30 for electron supply and n-type ohmic contact formation. Structure 30 may include a thick (2.0−5.0 μm such as 3.0 μm, n=2.0×10¹⁸−5.0×10¹⁸ cm⁻³) n-AlGaN layer 31 for current spreading, a heavily n-type doped (0.2-0.8 μm such as 0.60 μm, n=8×10¹⁸−2×10¹⁹ cm⁻³) n⁺-AlGaN layer 33 for MQW active-region polarization field screening, and a lightly doped n⁻-AlGaN layer 35 (0.1-0.5 μm such as 0.3 μm, n=2.5×10¹⁷−2×10¹⁸ cm⁻³) to reduce current crowding and prepare uniform current injection into the following Al_{b}Ga_{1-b}N/Al_{w}Ga_{1-w}N MQW active-region 40. MQW 40 is made of alternatingly stacked n-Al_{b}Ga_{1-b}N barrier and Al_{w}Ga_{1-w}N well for a few times, for example, for 3-8 times. The barrier thickness is in the range of 6-12 nm, and the well thickness is 0.9-4.0 nm. The total thickness of MQW 40 is usually less than 200 nm, for example, being 75 nm, 100 nm, or 150 nm. The n-Al_{b}Ga_{1-b}N barrier and Al_{w}Ga_{1-w}N well may have an Al-composition in the range of 0.3-1.0, and 0.0-0.85, respectively, and the Al-composition difference of the barrier and well is at least 0.15, or so to ensure a barrier-well bandgap width difference (Δ E_{g}) at least 400 meV to secure quantum confinement effect. Following MQW 40 is a p-AlGaN structure 50. Structure 50 can be a p-AlGaN layer of uniform or varying Al-composition, or a p-AlGaN superlattice structure, or a p-AlGaN MQW structure, or a p-AlGaN multilayer structure serving as hole injecting and electron blocking layer. Structure 50 has enough Al-composition and modulation to allow for sufficient electron blocking and hole injection efficiencies. Further, structure 50 is also efficient in spreading hole current laterally, and contains a hole supplier and p-contact layer, which can be a p-AlGaN layer with grading Al-content, or a p-AlGaN layer engineered according to U.S. Pat. No. 10,276,746, the content of which is herewith incorporated by reference in its entirety. To have high light extraction efficiency of deep UV LEDs, p-AlGaN structure 50 is preferrable to be UV transparent. Formed on p-AlGaN structure 50 is a reflector 71, serving as a p-ohmic contact and a light reflector as well. For example, reflector 71 can be a 50-125 nm thick rhodium (Rh) layer, a palladium (Pd) layer, or a molybdenum (Mo) layer. In one embodiment, reflector 71 is a compound reflector including a first reflector and a second reflector and a metal diffusion barrier layer inserted between the first and the second reflectors, with the first reflector formed in contact with p-AlGaN structure 50 serving as a p-ohmic contact. For example, the first reflector, the diffusion barrier and the second reflector can be a 5-25 nm thick Rh layer, a 5-25 nm thick Ti layer, and a 100-500 nm thick Al layer, respectively. In another embodiment, reflector 71 is a compound reflector including a transparent conductive oxide layer and a metal reflector and a metal diffusion barrier layer inserted between the transparent conductive oxide layer and the metal reflector, with the transparent conductive oxide layer formed in contact with p-AlGaN structure 50 serving as a p-ohmic contact. For example, the transparent conductive oxide layer, the diffusion barrier and the metal reflector can be a 5-25 nm thick indium tin oxide (ITO) layer, a 1-5 nm thick Ti layer, and a 100-500 nm thick Al layer, respectively. Formed over reflector 71 there is at least a thick metal layer serving as p-contact pad 79, which can be made of a 2-5 μm gold layer or gold tin layer.

Also formed on n-AlGaN structure 30 is an n-ohmic contact 81, which can be made of thin metal layer stacks such as titanium/aluminum/titanium/gold (Ti/Al/Ti/Au) with respective layer thickness of 30-40/70-80/10-20/80-100 nm, for example 35/75/15/90 nm, or V/Al/V/Ag, V/Al/V/Au, and V/Al/Ti/Au, of respective thicknesses such as 20/60/20/100 nm. As seen from FIG. 8, n-ohmic contact 81 is preferred to be formed on the heavily n-type doped n⁺-AlGaN layer 33. Overlying n-ohmic contact 81 is n-contact pad 89 made of a thick (2-5 μm) gold or gold tin layer.

During operation, electrons and holes will be injected into the MQW active-region 40 respectively from the n- and p-AlGaN structures 30 and 50, to radiatively recombine and emit UV light, which will be imping on interface I₁, formed between template 20 and substrate S₁. Even though the light-emitting structure L₁ contains many AlGaN layers of different Al-content, the refractive index contrast between these layers is trivial, and thus the whole light-emitting structure L₁ can be considered as of a single refractive index. The substrate surface pattern features formed on interfaces I₁ and I₂ according to the teachings given in this disclosure will enhance the light extraction efficiencies from light-emitting structure L₁ into substrate S₁, and from substrate S₁ into extraction medium M₁, respectively.

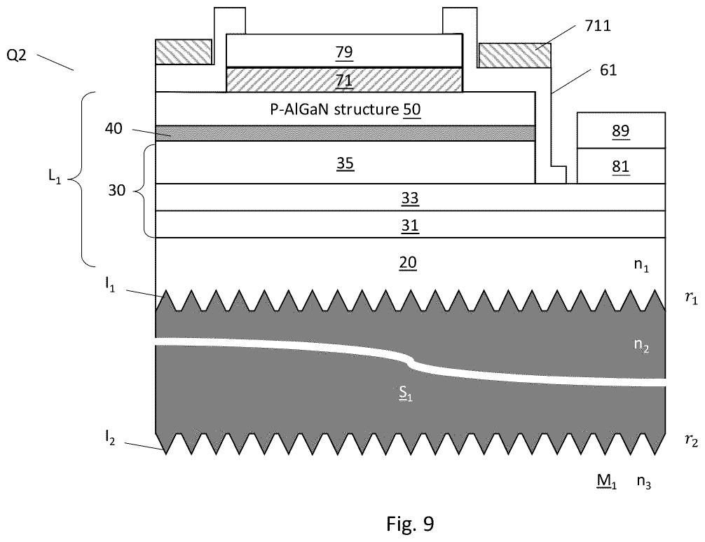

According to eq. (3), the reflectance R of the reflector 71 contributes constructively to the light extraction efficiency of the LED Q1. For this reason, the higher the R the better the light extraction efficiency, it is therefore desirable to have increased p-side reflectance of the LED in order to have a high-efficiency bottom emitting LED. To this goal, illustrated in FIG. 9 is a cross-sectional schematic view of a UV LED Q2, of similar structure to LED Q1 but with an auxiliary reflector 711 formed over the p-AlGaN structure 50 beside reflector 71. Reflector 711 is isolated from p-AlGaN structure 50 and reflector 71 by a transparent passivation layer 61, made of SiO₂, HfO₂, Al₂O₃, or MgF₂ et al. To have improved UV reflectance, reflector 711 can be an Al reflector, or a distributed Bragg reflector made of multiple SiO₂/HfO₂ layers. The area ratio of reflector 71 to reflector 711 is optionally in the range of 1.8-9.0.

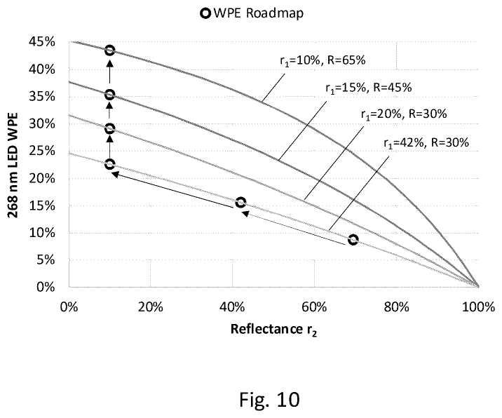

Deep UV LED embodiments Q1 and Q2 can have improved light extraction efficiency as compared to the prior art deep UV LEDs. According to the present disclosure, reduced interface reflectance at the semiconductor/substrate and substrate/extraction medium interfaces due to the double-surface patterned substrate S₁, transparency of p-AlGaN structure 50, and increased reflectance of reflectors 71 and 711 join force to promote a deep UV LED light extraction and wall-plug efficiencies up to 76% and 43%, respectively. FIG. 10 shows a roadmap of wall-plug efficiency for deep UV LEDs according to the present disclosure. Also shown are the wall-plug efficiency dependences on the reflectance R of the p-side reflector (71, 711), and on the reflectance at the semiconductor/substrate (r₁) and substrate/extraction medium (r₂) interfaces.

Light extraction and wall-plug efficiencies are compared in table 1 for some LEDs including a PSS blue LED with silicone lens, a thin-film blue LED, a PSS deep UV LED with fluoropolymer lens, and a double-surface patterned substrate (DSPS) deep UV LED according to embodiment Q2. As seen, so far, the most efficient LED is the thin-film blue LED, as it has the least optical interfaces (only two: I₀ and I₁) and the least backside reflectance. The DSPS deep UV LED according to this disclosure can have a light extraction and wall-plug efficiency of 76.2% and 43.4%, respectively. These efficiencies would approach those of an ideal thin-film deep UV LED. But thin-film deep UV LEDs are more difficult to fabricate than the DSPS deep UV LEDs disclosed in the present invention.

TABLE 1
Efficiency comparison of various LEDs

| | PSS blue LED | Thin film | PSS DUV LED | DSPS |
|---|---|---|---|---|
| | silicone lens | blue LED | fluoropolymer lens | DUV LED |
| R | 92.00% | 92.00% | 30.00% | 65.00% |
| r₁ | 26.54% | 26.54% | 41.96% | 10.00% |
| r₂ | 60.50% | 0.00% | 69.41% | 10.00% |
| Γ | 80.29% | 93.30% | 15.32% | 76.24% |
| IQE | 90% | 90% | 80% | 80% |
| V_{F} | 3.0 | 3.0 | 6.5 | 6.5 |
| λ, nm | 450 | 450 | 268 | 268 |
| WPE | 66.37% | 77.13% | 8.72% | 43.42% |

The present invention has used UV LEDs as exemplary embodiments. However, it is to be understood that the scope of the present invention is not limited to the disclosed embodiments. On the contrary, it is intended to cover various modifications and similar arrangement or equivalents which can be obtained by a person skilled in the art without creative work or undue experimentation. The scope of the claims, therefore, should be accorded the broadest interpretation so as to encompass all such modifications and similar arrangements and equivalents.

What is claimed is:

1. A light-emitting device comprising:
a light-emitting structure, comprising an n-type semiconductor structure, a light-emitting active region, and a p-type semiconductor structure;
a reflector formed on the p-type semiconductor structure;
a substrate, providing an epitaxy surface supporting the light-emitting structure and a backside surface extracting light out of the light-emitting device;
wherein the epitaxy surface is patterned with protrusion or depression features, the protrusion or depression features on the epitaxy surface have a small base dimension d₁ in the range of 0-400 nm, a large base dimension D₁ in the range of 500-1000 nm, and a feature depth or height H₁ in the range of 350-750 nm, and the epitaxy surface has a flat surface ratio in the range of 9-60%;
wherein the backside surface is patterned with protrusion or depression features, the protrusion or depression features on the backside surface have a small base dimension d₂ in the range of 0-400 nm, a large base dimension D₂ in the range of 800-3000 nm, and a feature depth or height H₂ in the range of 550-2100 nm, and the backside surface has a flat surface ratio in the range of 0-60%.

2. A light-emitting device according to claim 1, wherein the protrusion or depression features are of hexagonal packing.

3. A light-emitting device according to claim 2, wherein the protrusion or depression features on the epitaxy surface are cone protrusions or depressions having a period P₁ in the range of 600-1000 nm.

4. A light-emitting device according to claim 3, wherein the period and the diameters of the large and small cone bases on the epitaxy surface are selected to have a flat surface ratio r_{f} in the range of 9-39%.

5. A light-emitting device according to claim 2, wherein the protrusion or depression features on the backside surface have a period P₂ in the range of 1000-3000 nm.

6. A light-emitting device according to claim 5, wherein the period and the diameters of the large and small cone bases are selected to have a flat surface ratio r_{f} in the range of 0-30%.

7. A light-emitting device according to claim 1 wherein the reflector is a 50-125 nm thick rhodium metal layer.

8. A light-emitting device according to claim 1, wherein the reflector is a compound reflector including a first reflector and a second reflector and a metal diffusion barrier layer inserted between the first and the second reflectors, wherein the first reflector is formed in contact with the p-type semiconductor structure.

9. A light-emitting device according to claim 8, wherein the first reflector, the diffusion barrier and the second reflector are a 5-25 nm thick Rh layer, a 5-25 nm thick Ti layer, and a 100-500 nm thick Al layer, respectively.

10. A light-emitting device according to claim 1, wherein the reflector is a compound reflector including a transparent conductive oxide layer and a metal reflector and a metal diffusion barrier layer inserted between the transparent conductive oxide layer and the metal reflector, wherein the transparent conductive oxide layer formed in contact with the p-type semiconductor structure.

11. A light-emitting device according to claim 10, wherein the transparent conductive oxide layer, the diffusion barrier and the metal reflector are a 5-25 nm thick indium tin oxide (ITO) layer, a 1-5 nm thick Ti layer, and a 100-500 nm thick Al layer, respectively.

12. A light-emitting device according to claim 1, further comprising an auxiliary reflector separated from the reflector by a transparent passivation layer.

13. A light-emitting device according to claim 12, wherein the auxiliary reflector is an Al reflector or a distributed Bragg reflector made of multiple SiO₂/HfO₂ layers, and the transparent passivation layer is selected from SiO₂, HfO₂, Al₂O₃, or MgF₂.

14. A light-emitting device according to claim 1, wherein the n-type semiconductor structure, the light-emitting active region, and the p-type semiconductor structure are made of AlGaN materials, and the substrate is selected from sapphire, AlN, diamond, and quartz.

15. The light-emitting device according to claim 1, wherein the light-emitting active region emits light of wavelengths in the range of 200-360 nm.
